(19) United States
(12) Patent Application Publication
(10) Pub. No.: US 2007/0090384 A1
(43) Pub. Date: Apr. 26, 2007

(54) Nitride based semiconductor device having multiple layer buffer structure and fabrication method thereof

(76) Inventors: Liang-Wen Wu, Banciao City (TW); Fen-Ren Chien, Yonghe City (TW)

Correspondence Address: LIN & ASSOCIATES INTELLECTUAL PROPERTY, P.O. BOX 2339, SARATOGA, CA, 95070-0339, US

(21) Appl. No.: 11/244,737

(22) Filed: Oct. 6, 2005

(51) Int. Cl. H01L 33/00

(52) U.S. Cl. 257/99

(57) ABSTRACT

A multiple layered buffer structure for nitride based semiconductor device is provided herein. The buffer structure contains a first layer of AlₓIn_{y}Ga_{1-x-y}N grown under a high temperature, and a second layer of an un-doped or appropriately doped GaN based material grown under a low temperature The GaN based material of the second layer could be doped with Al, or In, or codoped with one of following sets of elements: Al/In, Si/In, Si/Al, Mg/In, Mg/Al, Si/Al/In, and Mg/Al/In. In another embodiment, the buffer structure contains a GaN seed layer, an AlInN thin layer, a GaN based main layer, and a GaN based thin layer. The GaN seed layer is grown under a high temperature while the other layers are grown under a low temperature.

### BACKGROUND OF THE INVENTION

1. Field of the Invention

The present invention generally relates to nitride based semiconductor devices, and more particularly to such a semiconductor device having a multiple layered buffer structure between the substrate and the main epitaxial structure and a related method for fabricating such the semiconductor device.

2. The Prior Arts

Conventionally, fabricating a nitride based semiconductor device for use as a light emitting laser device usually requires growing a buffer layer on top of the substrate so as to improve the crystallinity and the surface morphology of the main nitride based epitaxial structure subsequently grown on the buffer layer. Various approaches have been proposed for the formation of such a buffer layer in the related arts.

U.S. Pat. No. 5,290,393 proposes a crystal growth method for a gallium nitride (GaN) based compound semiconductor in which a buffer layer represented by the formula GaₓAl₁₋ₓN (0>x≦1) having a thickness of 0.001-0.5 μm is first grown on a substrate at a low temperature (between 200° C. and 900° C.) and, then, the main GaN epitaxial structure is grown at a high temperature (between 900° C. to 1150° C.).

U.S. Pat. No. 6,508,878 proposed a similar method for growing a GaN system compound semiconductor, in which an intermediate buffer layer having a super lattice structure made of InₓAl₁₋ₓN/AlN or InₓAl₁₋ₓN/GaN is first grown on a sapphire substrate at a first temperature and, then, a GaN or InₓGa₁₋ₓN system compound semiconductor is grown on the intermediate buffer layer at an elevated second temperature. The method also suggests having an optional GaN protection layer on top of the intermediate buffer layer for preventing vaporization of In contained in the intermediate buffer layer before elevating temperature for growing the system compound semiconductor.

U.S. Pat. No. 5,686,738 proposes yet another similar approach wherein a non-single crystalline buffer layer is also grown at a temperature lower than that of the growth layer formed subsequently. These prior approaches all have their buffer layer formed under a low temperature because, for one reason, if the growing temperature is too high (e.g., over 900° C.), the buffer layer would become monocrystalline and no longer perform the function of a buffer layer. Despite their effectiveness, the main nitride based epitaxial structure subsequently formed by these methods on the low-temperature buffer layer still suffers a crystal defect concentration as high as 10¹⁰/cm² resulted from too large a lattice mismatch between the substrate and the main nitride based epitaxial structure.

### SUMMARY OF THE INVENTION

In light of the high defect concentration problem of the conventional approaches, the present invention proposes to use a multiple layered buffer structure to replace the conventional buffer layer for nitride based semiconductor devices.

Two types of multiple layered buffer structure are provided herein. For the first type, the buffer structure contains a first layer of AlₓIn_{y}Ga_{1-x-y}N and a second layer of an un-doped or appropriately doped GaN based material, sequentially formed on a substrate in this order from bottom to top. The first layer is grown under a high temperature between 900° C. and 1100° C. up to a thickness between 5 Å and 20 Å, while the second layer is grown under a low temperature between 200° C. and 900° C. up to a thickness between 5 Å and 500 Å. The GaN based material of the second layer could be doped with Al, or In, or codoped with one of following sets of elements: Al/In, Si/In, Si/Al, Mg/In, Mg/Al, Si/Al/In, and Mg/Al/In.

For the second type, the buffer structure contains a GaN seed layer, an AlInN thin layer, a GaN based main layer, and a GaN based thin layer, sequentially formed on a substrate in this order from bottom to top. The GaN seed layer is grown under a high temperature between 900° C. and 1100° C. up to a thickness between 5 Å and 20 Å, while the other layers are grown under a low temperature between 200° C. and 900° C. up to a total thickness between 5 Å and 500 Å. There are two variants for the second type of embodiment. If the GaN based main layer is made of un-doped GaN, the GaN based thin layer could be made of InGaN or In-doped GaN. On the other hand, if the GaN based main layer is made of un-doped GaN, In-doped GaN, Si/In-codoped GaN, or Mg/In-codoped GaN, the GaN based thin layer is replaced by delta-doped In clusters.

The present invention also proposes fabrication methods for nitride based semiconductor devices having these multiple layered buffer structures. As outlined above, one of the most significant characteristic of the present invention lies in the use of a high growing temperature in forming the lower layer of the multiple layered buffer structure and then the use of a low growing temperature in forming the upper layer(s) of the buffer structure. Another major characteristic lies in the use of In in forming the upper layer(s) of the buffer structure so that the surface morphology of the upper layer(s) are greatly improved and a virtually featureless buffer structure could be obtained.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a schematic sectional view showing a nitride based semiconductor device in accordance with a first embodiment of present invention.

FIG. 2a is a schematic sectional view showing a nitride based semiconductor device in accordance with a second embodiment of present invention.

FIG. 2b is a schematic sectional view showing a nitride based semiconductor device in accordance with a third embodiment of present invention.

FIG. 3 is an energy gap vs. lattice constant diagram extracted from Sze, S.M. Physics of Semiconductor Devices, 2^{nd} ed. New York: Wiley, 1981.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

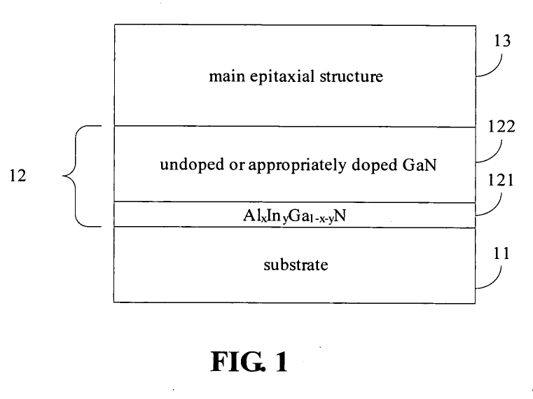

FIG. 1 is a schematic sectional view showing a nitride based semiconductor device in accordance with a first embodiment of the present invention. As illustrated, the nitride based semiconductor device of the present embodiment contains a dual layered buffer structure 12 between the substrate 11 and the main nitride based epitaxial structure 13. The buffer structure 12 contains a first layer 121 made of a quaternary nitride AlₓIn_{y}Ga_{1-x-y}N (x≧0, y≧0, l≧x+y≧0) having a thickness between 5 Å and 20 Å, and a second layer 122 made of an un-doped or appropriately doped GaN based material having a thickness between 5 Å and 500 Å. The first and second layers 121 and 122 are sequentially formed on the substrate 11 in this order from bottom to top.

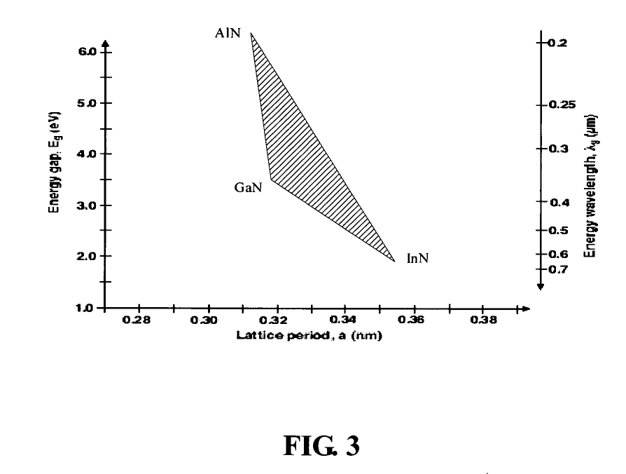

The reason why the quaternary nitride AlₓIn_{y}Ga_{1-x-y}N is chosen could be seen from FIG. 3, which is an energy gap vs. lattice constant diagram extracted from Sze, S.M. Physics of Semiconductor Devices, 2^{nd} ed. New York: Wiley, 1981. It should be quite common to people in the related arts that, by controlling its compositions, the quartemary compound AlₓIn_{y}Ga_{1-x-y}N could have its characteristics varied within the shaded area illustrated and, thereby, could achieve a better matched lattice constant to the underlying substrate 11 and to the overlaying main epitaxial structure 13.

The first layer 121 is grown on the substrate 11 using metalorganic chemical vapor deposition (MOCVD) at a temperature between 900° C. and 1100° C., relatively higher than the growing temperature of the second layer 122. A high temperature is used here so that the problem of defect concentration being too high which is commonly found in prior approaches could be improved. However, due to the fact that the substrate 11 and the first layer 121 could have such a large lattice mismatch, the AlₓIn_{y}Ga_{1-x-y}N of the first layer 121 would cluster and produce an un-even surface under such a high temperature which, if without amendment, would introduce defects and stacking faults to the main epitaxial structure subsequently formed on this un-even surface. A second layer 122 made of a GaN material is therefore adopted.

The GaN material of the second layer 122 could be doped with Al, or In, or codoped with one of following sets of elements: Al/In, Si/In, Si/Al, Mg/In, Mg/Al, Si/Al/In, and Mg/Al/In. The addition of the In atoms in the second layer 122 has a significant impact. When In atoms are added, the surface smoothness of the second layer 122 could be greatly enhanced and the defects and stacking faults of the main epitaxial structure could be effectively suppressed.

The second layer 122 is also grown on the first layer using MOCVD at a lower temperature between 200° C. and 900° C. Using a second layer 122 made of Mg/In doped GaN as example, trimethyl-gallium (TMGa), ammonia (NH₃), and bis-cyclopentadienylmagnesium (CP₂Mg) could be used as the Ga, N, and Mg source precursors. The In doping could be provided by trimethyl-indium (TMIn) diluted with hydrogen. After the multiple layered buffer structure 12 is formed, the temperature is elevated to a high temperature for re-crystallization, and the main nitride based epitaxial structure 13 is then grown at a high temperature as in conventional approaches.

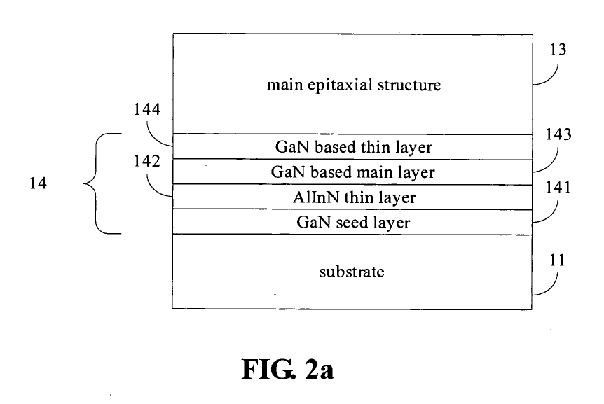

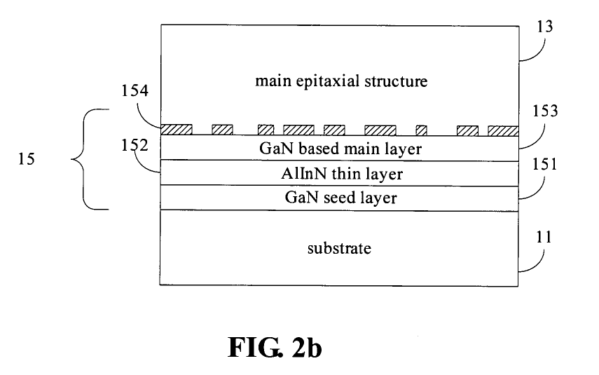

FIG. 2a is a schematic sectional view showing a nitride based semiconductor device in accordance with a second embodiment of present invention. As illustrated, the buffer structure 14 contains a GaN seed layer 141, an AlInN thin layer 142, a GaN based main layer 143, and a GaN based thin layer 144, sequentially formed on the substrate 11 in this order from bottom to top. The GaN seed layer 141 is grown under a high temperature between 900° C. and 1100° C. up to a thickness between 5 Å and 20 Å, while the other layers are grown under a low temperature between 200° C. and 900° C. up to a total thickness between 5 Å and 500 Å. The AlInN thin layer 142 is added which, jointly with the GaN seed layer 141, provides an effect equivalent to the first layer 121 of the previous embodiment.

On the other hand, the GaN based main layer 143 and the GaN based thin layer 144 jointly provide an effect equivalent to the second layer 122 of the first embodiment. The GaN based main layer is made of un-doped GaN, and the GaN based thin layer could be made of InGaN or In-doped GaN. After the multiple layered buffer structure 14 is formed, the temperature is elevated to a high temperature for re-crystallization, and the main nitride based epitaxial structure 13 is then grown at a high temperature as in conventional approaches.

FIG. 2b is a schematic sectional view showing a nitride based semiconductor device in accordance with a third embodiment of present invention. Basically, the present embodiment could be considered as a variant of the second embodiment. The buffer structure 15 of the present embodiment also contains a GaN seed layer 151, an AlInN thin layer 152, a GaN based main layer 153, and a plurality of randomly distributed In clusters 154, sequentially formed on the substrate 11 in this order from bottom to top. The GaN seed layer 151 is grown under a high temperature between 900° C. and 1100° C. up to a thickness between 5 Å A and 20 Å, while the other layers are grown under a low temperature between 200° C. and 900° C. up to a total thickness between 5 Å and 500 Å.

In the present embodiment, the GaN based main layer 153 is made of un-doped GaN, In-doped GaN, Si/In-codoped GaN, or Mg/In-codoped GaN. Additionally, instead of having a GaN based thin layer 144 such as the previous embodiment, the present embodiment deposits In on the GaN based main layer 153 using delta doping. As illustrated, the In atoms would form multiple randomly distributed clusters 154 on top of GaN based main layer 153. The reason to have In clusters on the GaN bulk crystal is that it can greatly reduce the density of dislocations by pinning the dislocations at the In atoms due to the larger radius of In atom than Ga atom. A much smoother surface morphology can thereby be obtained. Then the temperature is elevated to a high temperature for re-crystallization, and the main nitride base epitaxial structure 15 is grown on the GaN based main layer 153 and covers the In clusters 154 at a high temperature as in conventional approaches.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A nitride based semiconductor device comprising:
a substrate;
a dual layered buffer structure having a first layer made of AlₓIn_{y}Ga_{1-x-y}N (x≧0, y≧0, 1≧x+y≧0) on top of a surface of said substrate, and a second layer made of a GaN based material on top of said first layer; and
a nitride based epitaxial structure on top of said second layer of said dual layered buffer structure.

2. The nitride based semiconductor device according to claim 1, wherein said first layer has a thickness between 5 Å and 20 Å.

3. The nitride based semiconductor device according to claim 1, wherein said second layer has a thickness between 5 Å and 500 Å.

4. The nitride based semiconductor device according to claim 1, wherein said GaN based material of said second layer is un-doped GaN.

5. The nitride based semiconductor device according to claim 1, wherein said GaN based material of said second layer is GaN appropriately doped or codoped with one of the following sets of materials: Al, In, Al/In, Si/In, Si/Al, Mg/In, Mg/Al, Si/Al/In, and Mg/Al/In.

6. A method for fabricating a nitride based semiconductor device comprising the steps of:
growing a first layer made of AlₓIn_{y}Ga_{1-x-y}N (x≧0, y≧0, 1≧x+y≧0) on top of a surface of a substrate at a first temperature;
growing a second layer made of a GaN based material on top of said first layer at a second temperature lower than said first temperature;
elevating temperature for re-crystallization; and
growing a nitride based epitaxial structure on top of said second layer;
wherein said first layer and said second layer jointly function as a buffer structure for said semiconductor device.

7. The method according to claim 6, wherein said first layer has a thickness between 5 Å and 20 Å.

8. The method according to claim 6, wherein said second layer has a thickness between 5 Å and 500 Å.

9. The method according to claim 6, wherein said GaN based material of said second layer is un-doped GaN.

10. The method according to claim 6, wherein said GaN based material of said second layer is GaN appropriately doped or codoped with one of the following sets of materials: Al, In, Al/In, Si/In, Si/Al, Mg/In, Mg/Al, Si/Al/In, and Mg/Al/In.

11. The method according to claim 6, wherein said first temperature is between 900° C. and 1100° C.

12. The method according to claim 6, wherein said second temperature is between 200° C. and 900° C.

13. A nitride based semiconductor device comprising:
a substrate;
a multiple layered buffer structure having a GaN seed layer on top of a surface of said substrate, an AlInN thin layer, a GaN based main layer, and a GaN based thin layer sequentially stacked in this order on top of said GaN seed layer; and
a nitride based epitaxial structure on top of said GaN based thin layer of said multiple layered buffer structure.

14. The nitride based semiconductor device according to claim 13, wherein said GaN seed layer has a thickness between 5 Å and 20 Å.

15. The nitride based semiconductor device according to claim 13, wherein said AlInN thin layer, said GaN based main layer, and said GaN based thin layer has a total thickness between 5 Å and 500 Å.

16. The nitride based semiconductor device according to claim 13, wherein said GaN based main layer is made of un-doped GaN.

17. The nitride based semiconductor device according to claim 13, wherein said GaN based thin layer is made of one of the following materials: InGaN and In-doped GaN.

18. A method for fabricating a nitride based semiconductor device comprising the steps of:
growing a GaN seed layer on top of a surface of a substrate at a first temperature;
growing an AlInN thin layer, a GaN based main layer, and a GaN based thin layer sequentially in this order on top of said GaN seed layer at a second temperature lower than said first temperature;
elevating temperature for re-crystallization; and
growing a nitride based epitaxial structure on top of said GaN based thin layer;
wherein said GaN seed layer, said AlInN thin layer, said GaN based main layer,
and said GaN based thin layer jointly function as a buffer structure for said semiconductor device.

19. The nitride based semiconductor device according to claim 18, wherein said GaN seed layer has a thickness between 5 Å and 20 Å.

20. The nitride based semiconductor device according to claim 18, wherein said AlInN thin layer, said GaN based main layer, and said GaN based thin layer has a total thickness between 5 Å and 500 Å.

21. The nitride based semiconductor device according to claim 18, wherein said GaN based main layer is made of un-doped GaN.

22. The nitride based semiconductor device according to claim 18, wherein said GaN based thin layer is made of one of the following materials: InGaN and In-doped GaN.

23. The method according to claim 18, wherein said first temperature is between 900° C. and 1100° C.

24. The method according to claim 18, wherein said second temperature is between 200° C. and 900° C.

25. A nitride based semiconductor device comprising:
a substrate;
a multiple layered buffer structure having a GaN seed layer on top of a surface of said substrate, an AlInN thin layer, a GaN based main layer, and a plurality of In clusters sequentially stacked in this order on top of said GaN seed layer; and
a nitride based epitaxial structure on top of said multiple layered buffer structure.

26. The nitride based semiconductor device according to claim 25, wherein said GaN seed layer has a thickness between 5 Å and 20 Å.

27. The nitride based semiconductor device according to claim 25, wherein said AlInN thin layer, said GaN based main layer, and said In thin layer has a total thickness between 5 Å and 500 Å.

28. The nitride based semiconductor device according to claim 25, wherein said GaN based main layer is made of one of the following materials: un-doped GaN, In-doped GaN, Si/In-codoped GaN, and Mg/In-codoped GaN.

29. A method for fabricating a nitride based semiconductor device comprising the steps of:
growing a GaN seed layer on top of a surface of a substrate at a first temperature;
growing an AlInN thin layer and a GaN based main layer sequentially in this order on top of said GaN seed layer, and delta-doping In to form a plurality of In clusters on top of said GaN based main layer, all at a second temperature lower than said first temperature;
elevating temperature for re-crystallization; and
growing a nitride based epitaxial structure on top of said GaN based main layer to cover said plurality of In clusters;
wherein said GaN seed layer, said AlInN thin layer, said GaN based main layer,
and said plurality of said In clusters jointly function as a buffer structure for said semiconductor device.

30. The nitride based semiconductor device according to claim 29, wherein said GaN seed layer has a thickness between 5 Å and 20 Å.

31. The nitride based semiconductor device according to claim 29, wherein said AlInN thin layer, said GaN based main layer, and said In thin layer has a total thickness between 5 Å and 500 Å.

32. The nitride based semiconductor device according to claim 29, wherein said GaN based main layer is made of one of the following materials: un-doped GaN, In-doped GaN, Si/In-codoped GaN, and Mg/In-codoped GaN.

33. The method according to claim 29, wherein said first temperature is between 900° C. and 1100° C.

34. The method according to claim 29, wherein said second temperature is between 200° C. and 900° C.
